(19) United States
(12) Patent Application Publication
(10) Pub. No.: US 2013/0058060 A1
(43) Pub. Date: Mar. 7, 2013

(54) CONTROL PANEL ASSEMBLY AND LAUNDRY TREATING APPARATUS HAVING THE SAME

(71) Applicants: Yong Joon Jang, Suwon-si (KR); Myung Won Jeon, Suwon-si (KR)

(72) Inventors: Yong Joon Jang, Suwon-si (KR); Myung Won Jeon, Suwon-si (KR)

(73) Assignee: SAMSUNG ELECTRONICS CO., LTD., Suwon (KR)

(21) Appl. No.: 13/605,396

(22) Filed: Sep. 6, 2012

(30) Foreign Application Priority Data
Sep. 7, 2011 (KR) 10-2011-0090806

(51) Int. Cl. H05K 5/00

(52) U.S. Cl. 361/759

(57) ABSTRACT

A control panel assembly and a laundry treating apparatus having the same, the control panel assembly including a control panel, a Printed Circuit Board (PCB) provided at a rear side of the control panel, and a PCB housing configured to fix the PCB to the control panel, wherein the PCB housing includes a bottom plate and a sidewall that is extended from an end portion of the bottom plate, a fastening part is provided at the sidewall of the PCB housing for the PCB to be fastened to the PCB housing, the bottom plate includes at least one hook for the PCB to be fastened to the PCB housing and the PCB includes at least one accommodating hole to accommodate the at least one hook.

### CROSS-REFERENCE TO RELATED APPLICATIONS

This application claims the benefit of Korean Patent Application No. 10-2011-0090806, filed on Sep. 7, 2011 in the Korean Intellectual Property Office, the disclosure of which is incorporated herein by reference.

### BACKGROUND

1. Field

Embodiments of the present disclosure relate to a control panel assembly and a laundry treating apparatus having the same, and more particularly to, a control panel assembly having an improved fastening structure of a PCB (Printed Circuit Board) housing and an improved operating structure of a button part and a laundry treating apparatus having the same.

2. Description of the Related Art

In general, a laundry treating apparatus is designed to remove stain or unclean substance on a laundry through a chemical disintegration and a mechanical impact. A laundry treating apparatus includes a washing machine configured to remove stain or unclean substance from a laundry through a reciprocal interaction among water, detergent, and a rotating drum, and a drying machine configured to dry a laundry using a hot air heated by a heater.

The laundry treating apparatus is provided with a cabinet forming an exterior, a tub configured to store washing water, a rotating tub rotatably installed at an inside the tub, and a motor configured to rotate the rotating tub. When the rotating tub or a pulsator installed at an inside the rotating tub is rotated in a state that a laundry and washing water is introduced to an inside the rotating tub, friction is made among the washing water, the rotating tub, and the laundry and the stain on the laundry is removed.

The laundry treating apparatus is generally provided with a control panel assembly at an upper portion of a body that forms an exterior, and the control panel assembly is configured to control the operation of the laundry treating apparatus.

The control panel assembly is provided with a control panel having at least one opening on a side thereon and a PCB attached on a rear surface of the control panel. A plurality of button parts configured to operate a washing machine is provided at a front surface of the control panel. A tact switch is provided between the PCB and the plurality of button parts. The control of the operation of the laundry treating apparatus is performed as a user operates the button part to operate the tact switch, thereby controlling the PCB.

In order to fix the PCB to the control panel, the PCB is fixed to a PCB housing control panel. Conventionally, when a PCB is fixed to a PCB housing two or three screws on an outer edge of the PCB as well as on an inside the PCB. However, additional parts and process time may be needed in the screw coupling, and a board may be damaged when a coupling torque is increased during a coupling process of a PCB to a PCB housing.

In addition, in order to reduce a friction generated between the button part and the control panel, the button part is provided with a protrusion unit having a rectangular shape button part. However, a friction is increased according to the width and the size of the protrusion part, and as a result, the button part may fail to be restored. Accordingly, grease, to increase a restoration force, is used. However, when the grease is used, problems on the cost and the leakage of grease are present. When the width of the protrusion part is reduced, the protrusion part is easily damaged or is inadequate in reducing a friction.

### SUMMARY

Therefore, it is an aspect of the present disclosure to provide a control panel assembly configured to improve a fastening structure of a PCB and a PCB housing and to improve an operating structure of a control panel and a button part, and a laundry treating apparatus having the same.

Additional aspects of the disclosure will be set forth in part in the description which follows and, in part, will be apparent from the description, or may be learned by practice of the disclosure.

In accordance with one aspect of the present disclosure, a control panel assembly includes a control panel, a printed circuit board (PCB) and a PCB housing. The printed circuit board (PCB) is provided at a rear side of the control panel. The PCB housing is configured to fix the PCB to the control panel. The PCB housing includes a bottom plate and a sidewall that is extended from an end portion of the bottom plate. The bottom plate includes at least one hook for the PCB to be fastened to the PCB housing and the PCB includes at least one accommodating hole to accommodate the at least one hook.

The hook includes a body part extended from the PCB housing and a head part extended from the body part of the hook beyond the body part of the hook.

The hook includes a first hook and a second hook, and the accommodating hole includes a first accommodating hole and a second accommodating hole.

A head part of the first hook and a head part of the second hook are inserted to face an opposite direction to each other.

The first hook is inserted into the first accommodating hole, and the second hook is inserted into the second accommodating hole.

The first accommodating hole and the second accommodating hole are spaced apart from each other.

The first hook and the second hook are adjacent to each other, and are inserted into the first accommodating hole together with each other.

Each of the head part of the first hook and the head part of the second hook is inserted to be protruded toward an outer side of the PCB.

The head part of the first hook and the head part of the second hook are inserted in an opposite direction to each other, and each of the head part of the first hook and the head part of the second hook is inserted to be protruded toward an inner side of the PCB.

The control panel includes a button part, and the button part is provided at a portion of an edge thereof with a protrusion part protruding in a direction toward an outer side of the button part to reduce a friction area between the control panel and the button part.

The protrusion part is formed in a semi-sphere shape.

The protrusion part is formed in a wedge shape.

The control panel assembly further includes a support unit protruded from the PCB housing while being adjacent to the hook such that the PCB maintains a predetermined height when the PCB is fastened to the PCB housing.

The support unit is provided at both sides of the hook.

The support unit is provided in a way that the hook is surrounded by the support unit in a semicircular shape.

The control panel assembly further includes a fastening part provided at the sidewall of the PCB housing for the PCB to be fastened to the PCB housing.

An outer part of the head part of the hook includes an inclined surface formed in a slanted manner from an upper portion of the hook.

In accordance with another aspect of the present disclosure, a control panel assembly includes a control panel, a printed circuit board (PCB), a PCB housing, at least one hook, and at least one accommodating hole. The printed circuit board (PCB) is provided at a rear side of the control panel. The PCB housing is configured to fix the PCB to the control panel. The at least one hook is provided at an inner side of the PCB housing for the PCB to be fastened to the PCB housing. The at least one accommodating hole is included at an inner side of the PCB to accommodate the hook. The hook includes a first hook and a second hook, and the accommodating hole includes a first accommodating hole and a second accommodating hole, while the first hook is inserted into the first accommodating hole, and the second hook is inserted into the second accommodating hole.

The hook includes a body part extended from the PCB housing, and a head part extended from the body part beyond the body part of the hook. A head part of the first hook and a head part of the second hook are inserted opposite to each other.

The control panel includes a button part, and the button part is provided at a portion of an edge thereof with a protrusion part protruded in a direction toward an outer side of the button part to reduce a friction area between the control panel and the button part.

The protrusion part of the button part is protruded while having a semicircular shape.

In accordance with another aspect of the present disclosure, a laundry treating apparatus has a control panel assembly provided with a button part configured to control a laundry treating operation and a PCB, and includes a PCB housing configured to accommodate the PCB. The PCB housing includes a bottom plate and a sidewall extended from an end portion of the bottom plate. At least one hook is provided at the bottom plate of the PCB housing and at least one accommodation hole is provided at the PCB such that the PCB is fastened to the PCB housing. The hook includes a first hook and a second hook, and the accommodation hole includes a first accommodation hole and a second accommodation hole.

The hook includes a body part extended from the PCB housing, and a head part extended from the body part beyond the body part of the hook. A head part of the first hook and a head part of the second hook are inserted to face an opposite direction to each other.

The first hook is inserted into the first accommodating hole, and the second hook is inserted into the second accommodating hole, and the first accommodating hole and the second accommodating hole are spaced apart from each other.

The first hook and the second hook are adjacent to each other, and inserted into the first accommodating hole together with each other.

The laundry treating apparatus further includes a support unit protruded from the PCB housing while being adjacent to the hook such that the PCB maintains a predetermined height when the PCB is fastened to the PCB housing.

The button part is provided at a portion of an edge of the button part with a protrusion part protruded in a direction toward an outer side of the button part to reduce a friction area between the control panel and the button part, and the control panel includes an accommodating part corresponding to the protrusion part.

As described above, the time consumed and the number of parts needed to connect a PCB to a PCB housing may be reduced, as well as the friction between a button part and a control panel.

### BRIEF DESCRIPTION OF THE DRAWINGS

These and/or other aspects of the disclosure will become apparent and more readily appreciated from the following description of embodiments, taken in conjunction with the accompanying drawings of which:

FIG. 1 is a perspective view illustrating a laundry treating apparatus according to an embodiment of the present disclosure.

FIG. 2 is an exploded perspective view illustrating a control panel assembly of the laundry treating apparatus according to an embodiment of the present disclosure.

FIG. 3 is a view illustrating a PCB coupled to a PCB housing of the laundry treating apparatus according to an embodiment of the present disclosure.

FIG. 4 is a view illustrating a hook and a support unit of the laundry treating apparatus according to an embodiment of the present disclosure.

FIG. 5 is a cross sectional view illustrating a state of the PCB coupled to the PCB housing of the laundry treating apparatus according to an embodiment of the present disclosure.

FIG. 6 is a view illustrating a hook and a support unit of a laundry treating apparatus according to another embodiment of the present disclosure.

FIG. 7 is a view illustrating a hook and a support unit of a laundry treating apparatus according to still another embodiment of the present disclosure.

FIG. 8 is a view illustrating a cross section of a state of a PCB coupled to a PCB housing of the laundry treating apparatus of FIG. 7.

FIG. 9 is an enlarged view illustrating a rear side of the control panel and the button part according to an embodiment of the present disclosure.

FIG. 10 is a cross sectional view of the button part according to an embodiment of the present disclosure.

FIG. 11 is a view illustrating the button part according to an embodiment of the present disclosure.

FIG. 12 is a perspective view illustrating a rear side of the button part according to an embodiment of the present disclosure.

FIG. 13 is a view illustrating a button part according to another embodiment of the present disclosure.

### DETAILED DESCRIPTION

Reference will now be made in detail to embodiments of the present disclosure, examples of which are illustrated in the accompanying drawings, wherein like reference numerals refer to like elements throughout.

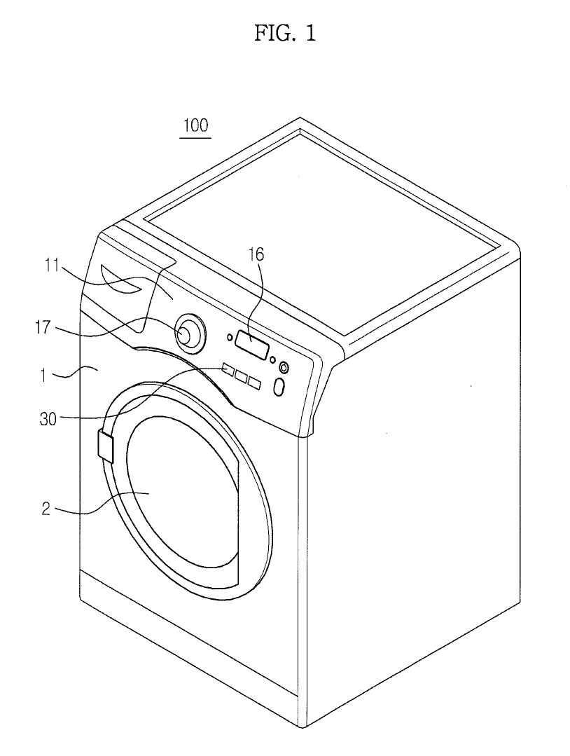

FIG. 1 is a perspective view illustrating a laundry treating apparatus according to an embodiment of the present disclosure.

As illustrated on FIG. 1, a laundry treating apparatus 100 according to an embodiment of the present disclosure includes a washing machine and a drying machine. The washing machine includes a body 1, a tub (not shown) installed at an inside the body 1 to store washing water, and a drum (now shown) rotatably installed at an inside the tub (not shown) to wash a laundry.

An inlet (not shown) is formed on a front portion of the body 1 to input a laundry to an inside of a drum (not shown), and a door 2 is installed to open/close the inlet. A control panel assembly 10 is provided at an upper portion of the body 1 for a user to control an operation of the laundry treating apparatus 100.

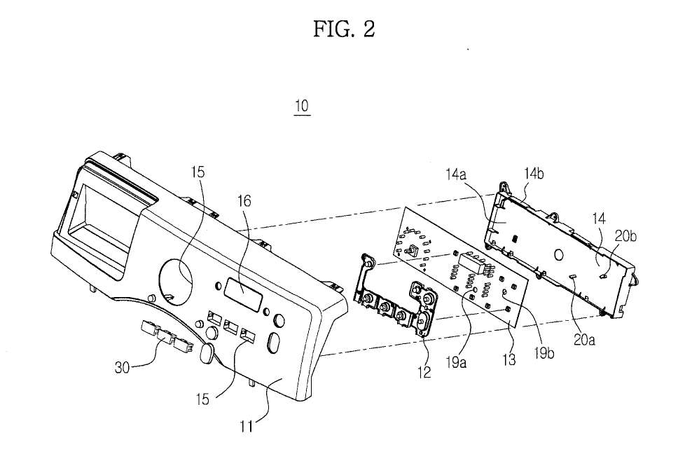

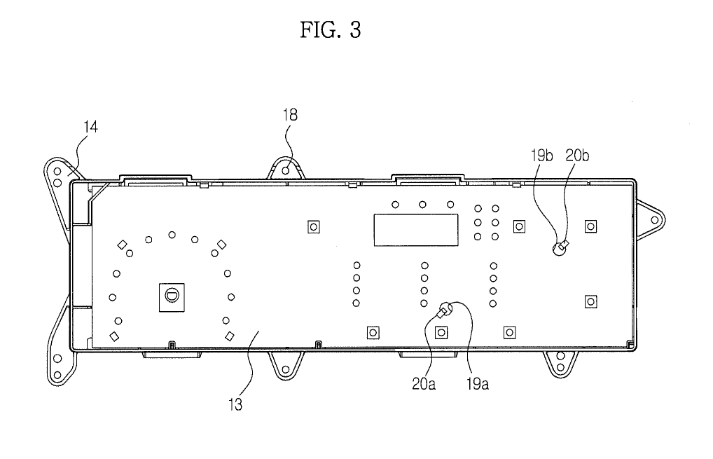

FIG. 2 is an exploded perspective view illustrating a control panel assembly of the laundry treating apparatus according to an embodiment of the present disclosure. FIG. 3 is a view illustrating a PCB coupled to a PCB housing of the laundry treating apparatus according to an embodiment of the present disclosure.

As illustrated on FIG. 2, the control panel assembly 10 according to an embodiment of the present disclosure includes a control panel 11, a button part 30, a tact switch 12, a Printed Circuit Board (PCB) 13 and a PCB housing 14.

The control panel 11 is detachably installed at an outer side of the laundry treating apparatus 100 while forming the exterior of the control panel assembly 10. In addition, a plurality of openings 15 allowing various input apparatuses and display apparatuses to be inserted therethrough is provided at the control panel 11. A text unit configured to indicate an operation condition of the laundry treating apparatus 100 may be provided at an outer surface of the control panel 11 while being adjacent to the opening 15. A display 16 is installed at one side of the control panel 11 to show the operating process of the laundry treating apparatus 100.

A operating knob 17 is inserted to the opening 15 of the control panel 11 while rotatably installed therein. A button part 30 is inserted into the opening 15 of the control panel 11 while installed therein so as to be pressed by a user. A tact switch 12 is provided at a position, which corresponds to the button part 30, at a lower portion of the button part 30 so as to be operated by a pressing of the button part 30. The tact switch 12 is configured to control a PCB 13, and, the tact switch 12 has the PCB 13 at a lower portion thereof such that the PCB 13 is controlled as the tact switch 12 is operated.

The operating knob 17 is rotatably installed at the opening 15 of the control panel 11 to be rotatably operated by a user, and the button part 30 is installed at the opening 15 of the control panel 11 to be elastically pressed by a user.

As illustrated on FIG. 3, the PCB housing 14 is configured to assemble the PCB 13 to the control panel 11. The PCB housing 14 includes a bottom plate 14a, and a sidewall 14b protruded from an end portion of the bottom plate 14a. According to an embodiment of the present disclosure, a hook 20 is provided at the bottom plate 14a of the PCB housing 14, and a fastening part 18 is provided at the sidewall 14b of the PCB housing 14. The fastening between the PCB housing 14 and the PCB 13 is achieved through the fastening part 18 of the sidewall 14b of the PCB housing 14. However, the hook 20 at an inner side of the PCB housing 14 increases the coupling strength between the PCB housing 14 and the PCB 13 and prevents the PCB 13 from being bent by heat. The number of hooks or fastening parts is not limited thereto. For example, one or more hooks or fastening parts may be provided to support coupling of the PCB 13 to the PCB housing 14. The hooks and the fastening parts may be provided in the predetermined locations of the PCB 13 and the PCB housing 14, respectively, to couple the PCB 13 to the PCB housing 14.

The PCB 13 is fastened to the PCB housing 14 by the hook 20 included at the inner side of the PCB housing 14 and an accommodating hole 19 provided at the PCB 13. The number of the accommodating holes may correspond to the number of hooks provided. Further, the location of the accommodating holes may correspond to the location of the hooks. The PCB 13, while being accommodated at the PCB housing 14, is fixed to the control panel 11 while being spaced apart from the PCB housing 14 by a predetermined interval. By having a space between the PCB 13 and the PCB housing 14, the tact switch 12 is prevented from being pressed and operated when the button unit 30 is not pressed.

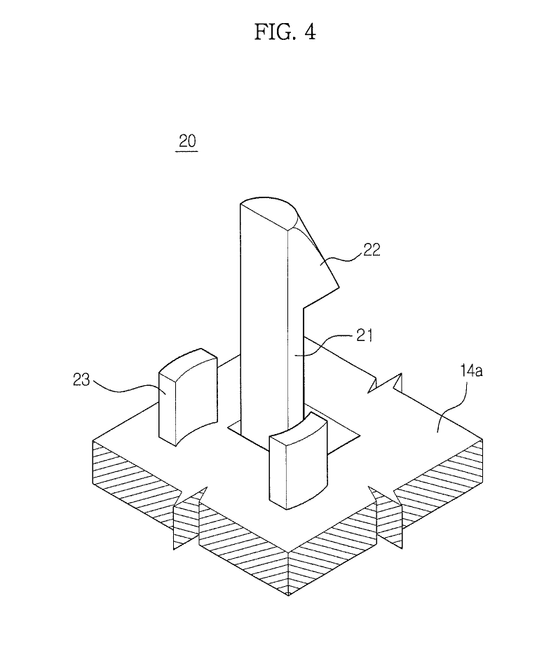

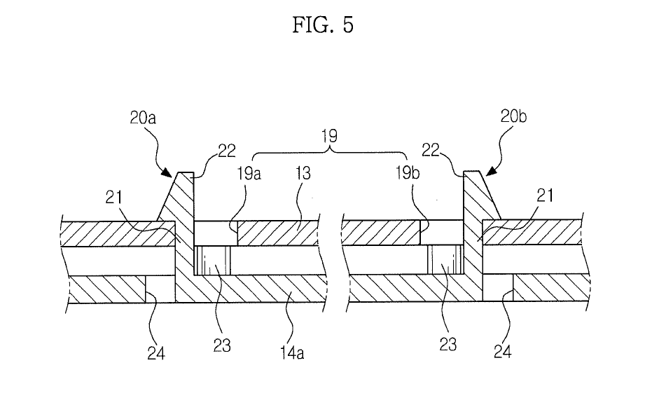

FIG. 4 is a view illustrating a hook and a support unit of the laundry treating apparatus according to an embodiment of the present disclosure. FIG. 5 is a cross sectional view illustrating a state of the PCB coupled to the PCB housing of the laundry treating apparatus according to an embodiment of the present disclosure.

As illustrated on FIG. 4, the hook 20 is provided at the PCB housing 14. The hook 20 includes a body part 21 extended from the PCB housing 14, and a head part 22 extended from the body part 21 beyond the body part 21 of the hook 20. As the head part 22 is protruded beyond the body part 21, the PCB 13 coupled to the PCB housing 14 may be prevented from being separated from the PCB housing 14.

According to an embodiment of the present disclosure, the head part 22 of the hook 20 is provided in an inclined manner and is formed in a triangular shape, but not limited herein. When the PCB 13 may be inserted into the PCB housing 14 through the fastening part 18 positioned at the sidewall 14b of the PCB housing 14, the hook 20 positioned at the bottom plate 14a of the PCB housing 14 may be inserted into the accommodating hole 19 included in the PCB 13 at the same time. The head part 22 provided in the inclined manner is inserted into the accommodating hole 19 and locked with the PCB 13 as shown in FIGS. 3 and 5. If more than one hook is provided, the directions of the locked head parts may not be the same. For example, as shown in FIG. 3, the head parts are locked in the opposite directions from each other.

According to an embodiment of the present disclosure, a support unit 23 is provided to maintain the height of the PCB 13 in a state that the PCB 13 and the PCB housing 14 are coupled to each other using the hook 20. The support unit 23 is provided at each side of the hook 20 while having a rectangular shape, but not limited herein.

As illustrated on FIG. 5, according to an embodiment of the present disclosure, the hook 20 includes a first hook 20a and a second hook 20b, and the accommodating hole 19 includes a first accommodating hole 19a and a second accommodating hole 19b. The first hook 20a is inserted into the first accommodating hole 19a, and the second hook 20b is inserted into the second accommodating hole 19b.

The first hook 20a and the second hook 20b are positioned while being spaced apart from each other, and the first accommodating hole 19a and the second accommodating hole 19b are provided at positions corresponding to the first hook 20a and the second hook 20b, respectively. Each of the head part 22 of the hook 20 is inserted into the accommodating hole 19 of the PCB 13 and locked with the PCB 13 by about 1 mm.

On the drawing, each of the head part 22 of the first hook 20a and the head part 22 of the second hook 20b is inserted into the PCB 13 in a way that each of the head part 22 of the first hook 20a and the head part 22 of the second hook 20b is hanging toward an outer side of the PCB 13, however, not limited herein, and each of the head part 22 of the first hook 20a and the head part 22 of the second hook 20b may be inserted into the PCB 13 in a way that each of the head part 22 of the first hook 20a and the head part 22 of the second hook 20b is hanging toward an inner side of the PCB 13. As each of the head part 22 of the first hook 20a and the head part 22 of the second hook 20b is inserted to an opposite direction to each other, the possibility of the PCB 13 being separated from the PCB housing 14 is reduced.

At the PCB housing 14, a hole 24 is provided at a side of the hook 20 for the convenience in manufacturing the PCB housing 14 having the hook 20 using a vertical ejection. However, when applying urethane liquid on the PCB 13 to prevent water from permeating thereinto, the PCB housing 14 is blocked. Therefore, the PCB housing 14 having the hook 20 is manufactured by using a slide-core in a molding, and thereby no hole 24 may be formed.

The PCB 13 and the PCB housing 14 may be formed with HIPS (High Impact Polystyrene), which is a type of polystyrene. As the PCB 13 and the PCB housing 14 are provided with certain flexibility, the hook 20 may be easily inserted into the accommodating hole 19. The PCB housing 14 may be formed with other materials that provide similar flexibility.

In addition, according to an embodiment of the present disclosure, a similar size of the accommodating hole 19 as in a conventional case of using a screw may be used, and therefore, a conventional PCB may continuously be used as the PCB 13.

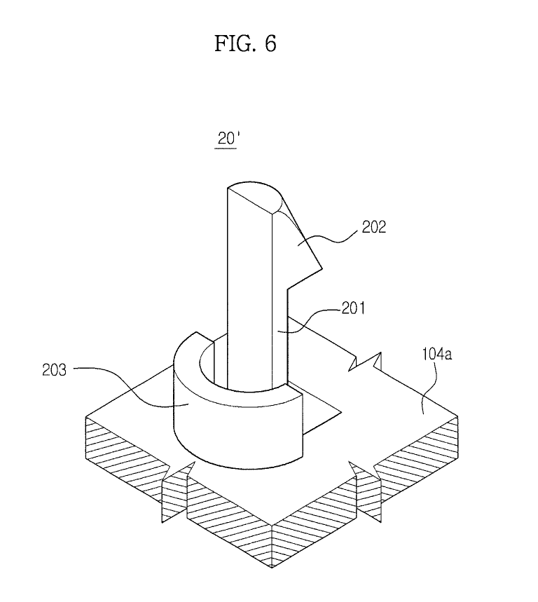

FIG. 6 is a view illustrating a hook and a support unit of a laundry treating apparatus according to another embodiment of the present disclosure. The hook 20′ includes a body part 201 extended from the bottom plate 104a of the PCB housing, and a head part 202 extended from the body part 201 beyond the body part 201 of the hook 20′. When compared to the first embodiment of the present disclosure illustrated on FIG. 4, there is a difference in the shape of a support unit 203. The support unit 203 is provided with a semicircular form and is positioned at an opposite side to the protruded direction of a head part 202 of a hook 20′, so that the PCB 13 may be stably supported.

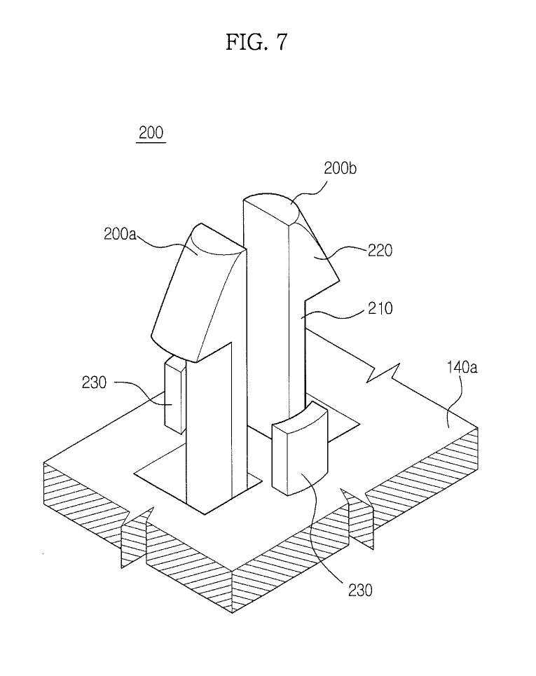

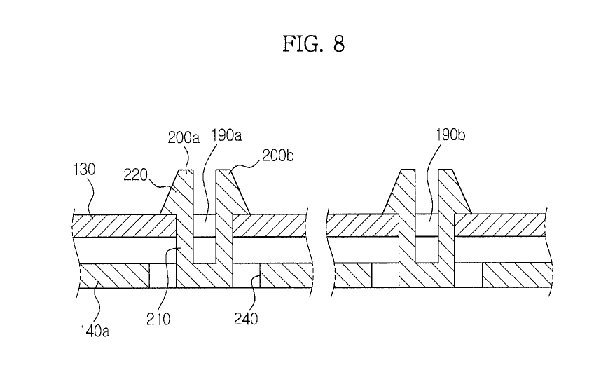

FIG. 7 is a view illustrating a hook and a support unit of a laundry treating apparatus according to still another embodiment of the present disclosure. FIG. 8 is a view illustrating a cross section of a state of a PCB coupled to a PCB housing of the laundry treating apparatus of FIG. 7.

A hook 200 includes a body part 210 extended from the bottom plate 140a of the PCB housing, and a head part 220 extended from the body part 210 beyond the body part 210 of the hook 200. The hook 200 includes a first hook 200a and a second hook 200b, and the first hook 200a and the second hook 200b are inserted into a single accommodating hole 190a. Another set of the hooks may be inserted into a single accommodating hole 190b, similarly. A head part 220 of the first hook 200a and a head part 220 of the second hook 200b are disposed while facing an opposite direction to each other. The head part 220 of the first hook 200a and the head part 220 of the second hook 200b are coupled to the single accommodating hole 190a on both sides of the single accommodating hole 190a, and are hooked at about 0.5 mm to the PCB 130.

According to an embodiment of the present disclosure illustrated on FIGS. 7 to 8, however, as a pair of the hook 200 is inserted into the single accommodating hole 190a, the size of the accommodating hole 190a provided at the PCB 130 may be larger than the conventional size. However, the size of the accommodating hole may not be limited thereto. For example, the size of the accommodating hole may be the same size as the conventional size while the hook may be smaller to be inserted into the accommodating hole.

A support unit 230 is positioned between the first hook 200a and the second hook 200b to maintain the height of the PCB 130. When the first hook 200a and the second hook 200b are inserted into the accommodating hole 190, the possibility of the PCB 130 being separated from the PCB housing 140 is reduced while the coupling strength is increased.

A hole 240 illustrated on FIG. 8 is provided for the convenience of the molding process to manufacture the molding of the hook 200.

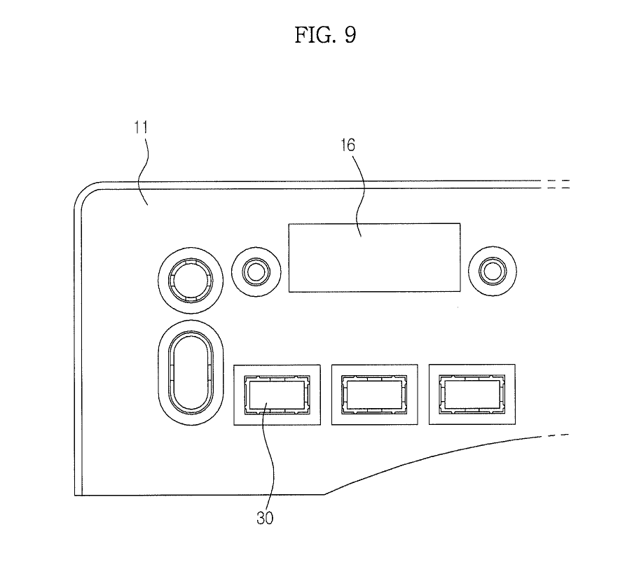

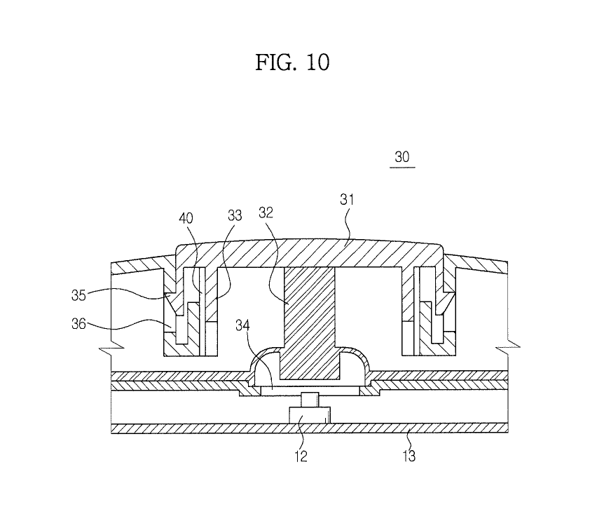

FIG. 9 is an enlarged view illustrating a rear side of the control panel and the button part according to an embodiment of the present disclosure. FIG. 10 is a cross sectional view of the button part according to an embodiment of the present disclosure.

The button part 30 is installed at the control panel 11, and the display 16 is provided at one side of the control panel 11 to show the operating state of the laundry treating apparatus. The tact switch 12 is provided at a lower portion of the button part 30 to control the operation of the PCB 13. According to the illustration on the drawing, the button part 30 is provided at the control panel 11, but not limited herein, and the button part 30 may be provided at the display 16. Further, the present disclosure may include the touch screen display unit to show the operating state of the laundry treating apparatus and control the operation of the laundry treating apparatus instead of the display 16 and the button part 30.

The button part 30 includes a cover part 33 having a pressing part 31 for a user to control, and a button rack 32 connected to a communicating hole 34, which is formed at a lower portion of the button part 30, to turn ON/OFF the tact switch 12 provided at a lower portion of the button part 30. The communicating hole 34 is provided at a lower portion of the cover part 33 for the button rack 32 to move therethrough.

In addition, the button part 30 may include an elastic part (not shown) elastically supporting the pressing part 31. The elastic part is configured to push the pressing part 31 upward when a user presses the pressing part 31. The elastic part (not shown) may be formed with rubber material.

A locking part 35 is provided at some portion of four sides of the button part 30 and inserted into a locking groove 36 provided at the control panel, thereby preventing the button part 35 from being shaken.

Thus, when a user presses the pressing part 31 of the button part 30, the button rack 32 operates the tact switch 12 by passing through the communicating hole 34 to convey a command to the PCB 13, and the operating control of the laundry treating apparatus 100 is performed.

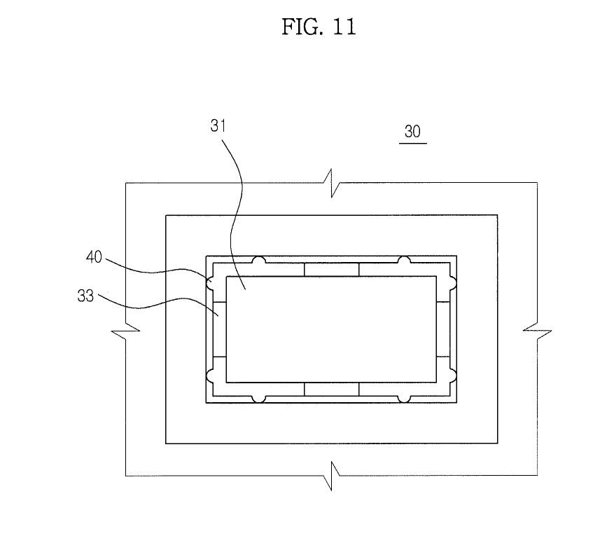

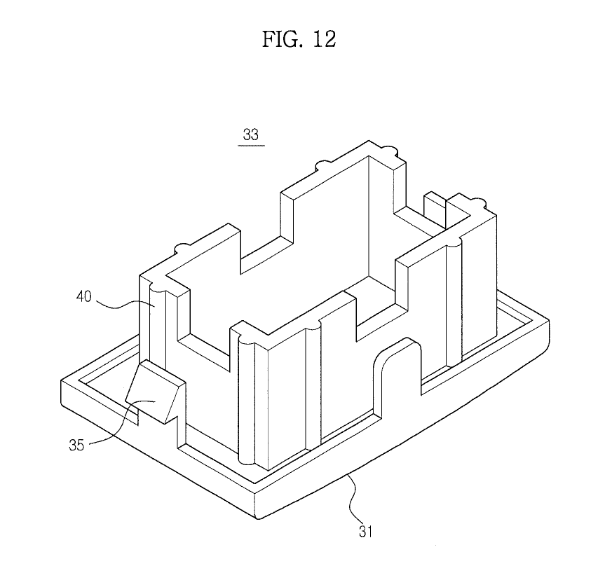

FIG. 11 is a view illustrating the button part according to an embodiment of the present disclosure. FIG. 12 is a perspective view illustrating a rear side of the button part according to an embodiment of the present disclosure.

The cover part 33 is provided at a portion of an edge thereof with a protrusion part 40 that is configured to prevent a button from moving laterally and being shaken and to reduce a friction between the button part 30 and the control panel 11 while minimize the interval between the button part 30 and the control panel 11. On the drawing, as the protrusion part 40 is provided at both sides of each corner of the button part 30, the total of eight protrusion parts 40 are provided. However, the number of the protrusion parts is not limited.

According to an embodiment of the present disclosure, the protrusion part 40 is protruded in a direction toward an outer side of the button part 30 while having a semicircular shape. When the semicircular shape, the button part 30 and the control panel 11 make contact on a line, not on a surface, thereby reducing the friction between the button part 30 and the control panel 11 when compared to other cases having different shapes of the protrusion part 40.

Thus, as the button part 30 and the control panel 11 make contact on a line, the friction thereinbetween is not increased, even in a case when the width of the protrusion part 40 is increased to prevent the button part 30 from being shaken, and the motion of the button part 30 is improved, thereby preventing the phenomenon of the button not being restored to an original position. In addition, grease may not be used, and therefore, the work time and the manufacturing cost may be reduced.

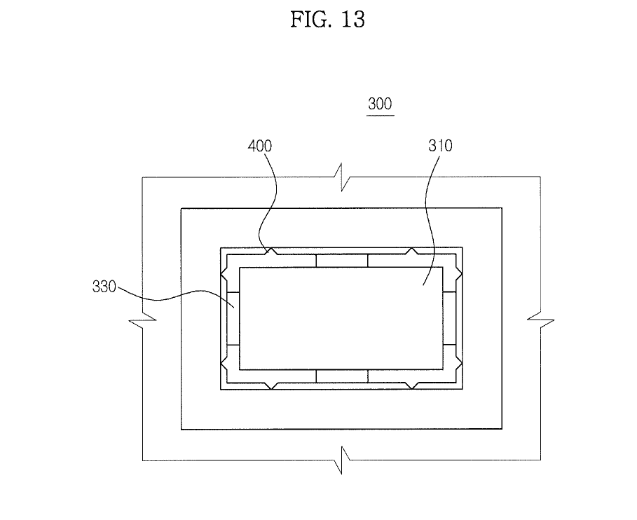

FIG. 13 is a view illustrating a button part according to another embodiment of the present disclosure.

A button part 300 includes a cover part 330 having a pressing part 310 for a user to control. As illustrated on FIG. 13, a protrusion part 400 is provided with a wedge shape, and similar to a semicircular shape, the protrusion part 400 makes contact with the control panel 11 on a line, thereby reducing a friction area thereinbetween.

Although a few embodiments of the present disclosure have been shown and described, it would be appreciated by those skilled in the art that changes may be made in these embodiments without departing from the principles and spirit of the disclosure, the scope of which is defined in the claims and their equivalents.

What is claimed is:

1. A control panel assembly, comprising:
a control panel,
a Printed Circuit Board (PCB) provided at a rear side of the control panel, and
a PCB housing configured to fix the PCB to the control panel,
wherein the PCB housing comprises a bottom plate and a sidewall extended from an end portion of the bottom plate, and
the bottom plate comprises at least one hook for the PCB to be fastened to the PCB housing and the PCB comprises at least one accommodating hole to accommodate the at least one hook.

2. The control panel assembly of claim 1, wherein the hook comprises a body part extended from the PCB housing and a head part extended from the body part of the hook beyond the body part of the hook.

3. The control panel assembly of claim 2, wherein the hook comprises a first hook and a second hook, and the accommodating hole comprises a first accommodating hole and a second accommodating hole.

4. The control panel assembly of claim 2, wherein a head part of the first hook and a head part of the second hook are inserted to face an opposite direction to each other.

5. The control panel assembly of claim 3, wherein the first hook is inserted into the first accommodating hole, and the second hook is inserted into the second accommodating hole.

6. The control panel assembly of claim 5, wherein the first accommodating hole and the second accommodating hole are spaced apart from each other.

7. The control panel assembly of claim 3, wherein the first hook and the second hook are adjacent to each other, and are inserted into the first accommodating hole together with each other.

8. The control panel assembly of claim 4, wherein each of the head part of the first hook and the head part of the second hook is inserted to be protruded toward an outer side of the PCB.

9. The control panel assembly of claim 5, wherein the head part of the first hook and the head part of the second hook are inserted to face an opposite direction to each other, and each of the head part of the first hook and the head part of the second hook is inserted to be protruded toward an inner side of the PCB.

10. The control panel assembly of claim 1, wherein the control panel comprises a button part, and
the button part is provided at a portion of an edge thereof with a protrusion part protruded in a direction toward an outer side of the button part to reduce a friction area between the control panel and the button part.

11. The control panel assembly of claim 10, wherein the protrusion part is formed in a semi-sphere shape.

12. The control panel assembly of claim 10, wherein the protrusion part is formed in a wedge shape.

13. The control panel assembly of claim 1, further comprising:
a support unit protruded from the PCB housing while being adjacent to the hook such that the PCB maintains a predetermined height when the PCB is fastened to the PCB housing.

14. The control panel assembly of claim 13, wherein the support unit is provided at both sides of the hook.

15. The control panel assembly of claim 13, wherein the support unit is provided in a way that the hook is surrounded by the support unit in a semicircular shape.

16. The control panel assembly of claim 1, further comprising:
a fastening part provided at the sidewall of the PCB housing for the PCB to be fastened to the PCB housing.

17. The control panel assembly of claim 2, wherein an outer part of the head part of the hook comprises an inclined surface formed in a slanted manner from an upper portion of the hook.

18. A control panel assembly, comprising:
a control panel;
a printed circuit board (PCB) provided at a rear side f the control panel;
a PCB housing configured to fix the PCB to the control panel;
at least one hook provided at an inner side of the PCB housing for the PCB to be fastened to the PCB housing; and
at least one accommodating hole included at an inner side of the PCB to accommodate the hook,
wherein the hook comprises a first hook and a second hook, and the accommodating hole comprises a first accommodating hole and a second accommodating hole, while the first hook is inserted into the first accommodating hole, and the second hook is inserted into the second accommodating hole.

19. The control panel assembly of claim 18, wherein the hook comprises a body part extended from the PCB housing, and a head part extended from the body part beyond the body part of the hook, and
a head part of the first hook and a head part of the second hook are inserted to face an opposite direction to each other.

20. The control panel assembly of claim 18, wherein the control panel comprises a button part, and
the button part is provided at a portion of an edge thereof with a protrusion part protruded in a direction toward an outer side of the button part to reduce a friction area between the control panel and the button part.

21. The control panel assembly of claim 20, wherein the protrusion part of the button part is protruded while having a semicircular shape.

22. A laundry treating apparatus having a control panel assembly provided with a button part and a PCB configured to control a laundry treating operation the laundry treating apparatus comprising:
a PCB housing configured to accommodate the PCB,
wherein the PCB housing comprises a bottom plate and a sidewall extended from an end portion of the bottom plate,
wherein at least one hook is provided at the bottom plate of the PCB housing and at least one accommodation hole is provided at the PCB such that the PCB is fastened to the PCB housing; and
wherein the hook comprises a first hook and a second hook, and the accommodation hole comprises a first accommodation hole and a second accommodation hole.

23. The laundry treating apparatus of claim 22, wherein the hook comprises a body part extended from the PCB housing, and a head part extended from the body part beyond the body part of the hook, and
a head part of the first hook and a head part of the second hook are inserted to face an opposite direction to each other.

24. The laundry treating apparatus of claim 23, wherein the first hook is inserted into the first accommodating hole, and the second hook is inserted into the second accommodating hole, and
the first accommodating hole and the second accommodating hole are spaced apart from each other.

25. The laundry treating apparatus of claim 23, wherein the first hook and the second hook are adjacent to each other, and inserted into the first accommodating hole together with each other.

26. The laundry treating apparatus of claim 22, further comprising:
a support unit protruded from the PCB housing while being adjacent to the hook such that the PCB maintains a predetermined height when the PCB is fastened to the PCB housing.

27. The laundry treating apparatus of claim 22, wherein the button part is provided at a portion of an edge thereof with a protrusion part protruded in a direction toward an outer side of the button part to reduce a friction area between the control panel and the button part, and the control panel comprises an accommodating part corresponding to the protrusion part.
